(19) United States
(12) Patent Application Publication
(10) Pub. No.: US 2015/0063039 A1
(43) Pub. Date: Mar. 5, 2015

(54) REDUNDANCY IN STACKED MEMORY STRUCTURE

(71) Applicant: TAIWAN SEMICONDUCTOR MANUFACTURING COMPANY LTD., Hsinchu (TW)

(72) Inventors: CHIEN-YUAN CHEN, HSINCHU CITY (TW); CHIEN-YU HUANG, HSINCHU CITY (TW); YI-TZU CHEN, HSINCHU (TW); HAU-TAI SHIEH, HSINCHU CITY (TW)

(73) Assignee: TAIWAN SEMICONDUCTOR MANUFACTURING COMPANY LTD., Hsinchu (TW)

(21) Appl. No.: 14/014,107

(22) Filed: Aug. 29, 2013

(51) Int. Cl. G11C 29/04

(52) U.S. Cl. CPC G11C 29/04
USPC 365/189.02; 365/200

(57) ABSTRACT

A circuit includes stacked memory arrays and a control circuit. The stacked memory arrays includes a first layer and a second layer. The control circuit is configured to receive a first address in the first layer; cause the second layer to be enabled for accessing; and provide a second row address for accessing the second layer.

### TECHNICAL FIELD

The present disclosure is related to redundancy in stacked memory structure.

### BACKGROUND

Memory chips are configured with redundant rows and/or redundant columns to repair a certain number of memory faults detected during testing of the memory chips. In some approaches, for more number of memory faults in a two-dimensional memory chip to be repairable, redundant rows and/or redundant columns are expanded along the x-dimension and/or the y-dimension.

However, along with the trend of higher density, higher performance and/or lower power memory chips, the number of memory faults occurred in memory chips become higher. To accommodate the increase in memory faults, more redundant rows and/or redundant columns are appended along the x-dimension and/or the y-dimension of the memory chip and therefore increase area of the memory chip. In addition, with the increase in the number of redundant columns appended along the y-dimension, column redundancy multiplexing circuits configured to shift data to be applied to or applied from the redundant columns increase in number for more shift operations. Hence, time for reading or writing data is increased. As a result, there is a need to solve the above deficiencies.

### BRIEF DESCRIPTION OF THE DRAWINGS

The details of one or more embodiments of the disclosure are set forth in the accompanying drawings and the description below. Other features and advantages of the disclosure will be apparent from the description, drawings and claims.

FIG. 1 is a schematic perspective diagram of a stacked memory structure with layer redundancy in accordance with some embodiments.

FIG. 2 is a diagram of flow charts of a method for accessing the stacked memory structure in FIG. 1 in accordance with some embodiments.

FIG. 3 is a schematic perspective diagram of a stacked memory structure with layer redundancy in accordance with some embodiments.

FIG. 4 is a schematic perspective diagram of a stacked memory structure with row redundancy and/or column redundancy in accordance with some embodiments.

FIG. 5 is a top-view diagram of a layer in the stacked memory structure in FIG. 4 in accordance with some embodiments.

FIG. 6 is a diagram of flow charts of a method for accessing the stacked memory structure in FIG. 4 in accordance with some embodiments.

FIG. 7 is a diagram showing flow charts of a method for accessing the stacked memory structure in FIG. 4 in accordance with some embodiments.

FIG. 8 is a schematic perspective diagram of a stacked memory structure with row redundancy and/or column redundancy in accordance with some embodiments.

Like reference symbols in the various drawings indicate like elements.

### DETAIL DESCRIPTION

Embodiments, or examples, of the disclosure illustrated in the drawings are now described using specific languages. It will nevertheless be understood that no limitation of the scope of the disclosure is thereby intended. Any alterations and modifications in the described embodiments, and any further applications of principles described in this document are contemplated as would normally occur to one of ordinary skill in the art to which the disclosure relates. Reference numbers may be repeated throughout the embodiments, but this does not necessarily require that feature(s) of one embodiment apply to another embodiment, even if they share the same reference number. It will be understood that when an element is referred to as being “connected to” or “coupled to” another element, it may be directly connected to or coupled to the other element, or intervening elements may be present.

In the below description, a signal is asserted with a logical high value to activate a corresponding device when the device is active high. In contrast, the signal is deasserted with a low logical value to deactivate the corresponding device. When the device is active low, however, the signal is asserted with a low logical value to activate the device, and is deasserted with a high logical value to deactivate the device.

### Stacked Memory Structure With Redundancy

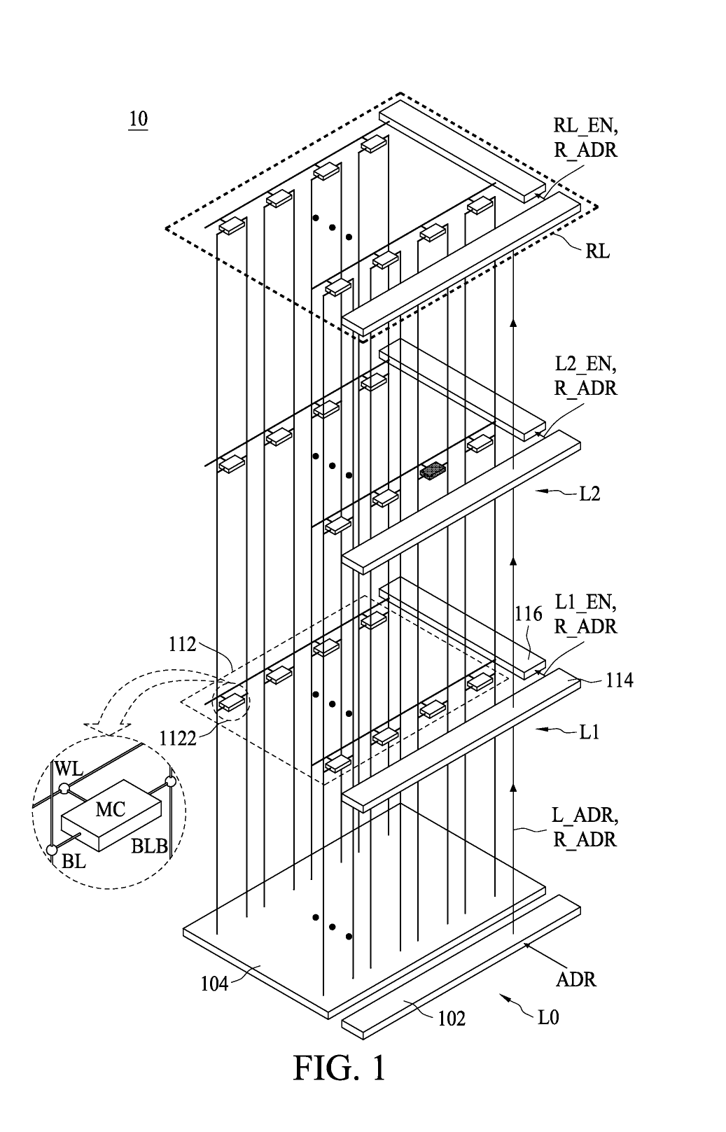

FIG. 1 is a schematic perspective diagram of a stacked memory structure 10 with layer redundancy in accordance with some embodiments. In the illustration of FIG. 1, the stacked memory structure 10 is configured with a redundant layer RL for replacing a defective regular layer L2 with, for example, one or more defective memory cells, and/or one or more defective word lines. The stacked memory structure 10 includes a control and IO (input and output) layer L0, a regular layer L1, the regular layer L2, and the redundant layer RL. The layer L0 includes a control circuit 102 and an IO circuit 104. Each of the layers L1, L2 and RL includes a memory array 112, a layer decoding circuit 114 and a row decoding circuit 116. For simplicity, the memory array 112 and its components, the layer decoding circuit 114 and the row decoding circuit 116 are labeled in the layer L1 but not in the layers L2 and RL. The memory array 112 includes 4×4 memory cells MC, one of which is shown in a zoomed-in portion 1122 of the memory array 112. Other memory cells MC of the memory array 112 have the same configuration as that shown in the zoomed-in portion 1122. The stacked memory structure 10 is exemplary. A stacked memory structure with other number of regular layers and redundant layers, and other number of memory arrays in each layer, and other number of memory cells in each memory array are within the contemplated scope of the present disclosure.

As illustrated in the zoomed-in portion 1122 of the memory array 112, the memory cell MC is coupled to a word line WL, a bit line BL, and a complementary bit line BLB. The word line WL is configured for passing of data to be written to or read from the memory cell MC to be controlled therethrough. The bit line BL and the complementary bit BLB are configured for differential voltages representing the data to be written to or read from the memory cell MC to be passed therethrough. The configuration of memory cell MC illustrated in the zoomed-in portion 1122 is exemplary. The memory cell MC can be a memory cell of any type of readable and writable memory such as static random access memory (SRAM) and dynamic random access memory (DRAM). Further, a configuration of memory cell MC with other number of word lines and bit lines are within the contemplated scope of the present disclosure.

In the stacked memory structure 10, each row of memory cells MC in the corresponding layer L1, L2 or RL is coupled to a respective word line WL. Each vertical column of memory cells MC across different layers L1, L2, and RL is coupled to a bit line BL and a complementary bit line BLB. In some embodiments, the bit line BL and the complementary bit line BLB of each vertical column are implemented using TSVs (Through Substrate Vias), ILVs (Inter-Layer Vias), vias and/or metal lines.

The control circuit 102 is configured to receive an address ADR of one or more memory cells to be accessed, and generate a layer address L_ADR of the regular layer L1 or L2 or the redundant layer RL, and a row address R_ADR of a row in the layer to which the layer address L_ADR corresponds. In some embodiments, the control circuit 102 includes fuses programmed for converting a matched layer address of a defective regular layer, L2 for example, to the layer address L_ADR of the redundant layer RL.

Each layer decoding circuit 114 is configured to receive the layer address L_ADR, and the row address R_ADR from the control circuit 102, and generate an asserted layer enable signal L1_EN, L2_EN or RL_EN if the received layer address L_ADR corresponds to the residing layer L1, L2 or RL of the layer decoding circuit 114. Each layer decoding circuit 114 is also configured to pass the row address R_ADR along with the layer enable signal L1_EN, L2_EN or RL_EN. In some embodiments, the layer address L_ADR and the row address R_ADR are passed vertically to different layers L1, L2, and RL using TSVs, ILVs, vias and/or metal lines. In other embodiments, the layer address L_ADR and the row address R_ADR are passed vertically to different layers L1, L2, and RL using TSVs, ILVs, vias and/or metal lines.

Each row decoding circuit 116 is configured to receive the layer enable signal L1_EN, L2_EN or RL_EN and the row address R_ADR from the corresponding layer decoding circuit 114, and selects one of the rows in the corresponding memory array 112 based on the row address R_ADR when the layer enable signal L1_EN, L2_EN or RL_EN is asserted.

The IO circuit 104 is configured to send or receive data to or from the selected row in the layer L1, L2 or RL through the corresponding bit lines BL and complementary bit lines BLB. In some embodiments, the IO circuit 104 includes for each vertical column of memory cells, a sense amplifier, a data driver and a flip flop or latch circuit, not shown for simplicity. Each sense amplifier is configured to sense data based on differential voltages received through the corresponding bit line BL and complementary bit line BLB during a read operation. Each data driver is configured to drive the corresponding bit line BL and complementary bit line BLB based on data to be written during a write operation. Each flip flop or latch circuit is configured to store the read data or the data to be written.

The organization of functional blocks in FIG. 1 is exemplary. For example, in other embodiments, the layer decoding circuits 114 of the layers L1, L2 and RL are configured in the control circuit 102, and the control circuit 102 generates the enable signals L1_EN, L2_EN and RL_EN, as well as the row address R_ADR based on the received address ADR. The enable signal L1_EN, L2_EN or RL_EN and the row address R_ADR are passed vertically to the corresponding layer L1, L2 or RL using TSVs, ILVs, vias and/or metal lines.

### Method for Accessing Stacked Memory Structure With Redundancy

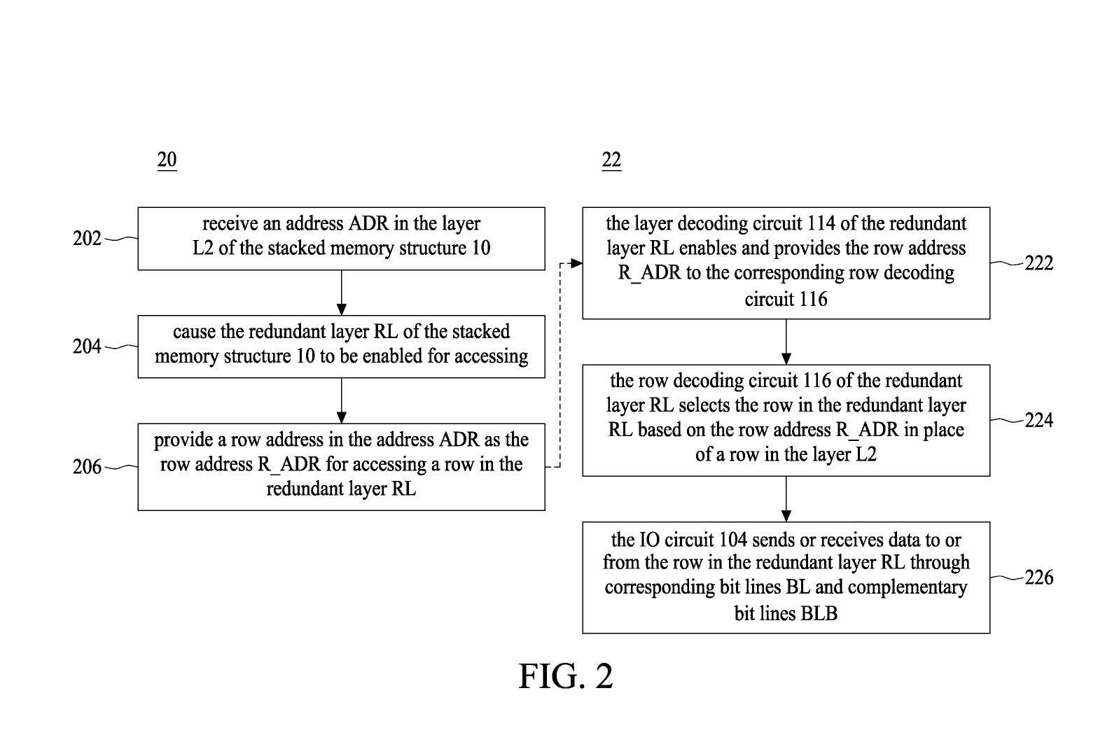

FIG. 2 is a diagram of flow charts 20 and 22 of a method for accessing the stacked memory structure 10 in FIG. 1 in accordance with some embodiments. In the illustration of FIG. 2, a row repaired by a corresponding row in the redundant layer RL is accessed. The flow chart 20 includes operations performed by the control circuit 102, and the flow chart 22 includes operations performed by other portions of the stacked memory structure 10 in response to the operations of the control circuit 102.

In the flow chart 20, in operation 202, an address ADR in the layer L2 of the stacked memory structure 10 is received.

In operation 204, the redundant layer RL of the stacked memory structure 10 is caused to be enabled for accessing. In some embodiments, the control circuit 102 converts a layer address received in the address ADR to the layer address L_ADR of the redundant layer RL and sends the layer address L_ADR to cause the redundant layer RL to be enabled.

In operation 206, a row address in the address ADR is provided as the row address R_ADR for accessing a row in the redundant layer RL.

In the flow chart 22, in operation 222, in response to the received layer address L_ADR and row address R_ADR, the row decoding circuit 116 of the redundant layer RL is enabled and provided with the row address R_ADR by the layer decoding circuit 114. In some embodiments, the layer decoding circuit 114 of the redundant layer RL sends an asserted layer enable signal RL_EN to enable the corresponding row decoding circuit 116.

In operation 224, the row in the redundant layer RL is selected based on the row address R_ADR by the row decoding circuit 116 to replace a row in the layer L2.

In operation 226, data are sent to or received from the row in the redundant layer RL by the IO circuit 104 through corresponding bit lines BL and complementary bit lines BLB.

In the embodiments described with reference to FIG. 1, the redundant layer RL is stacked in the stacked memory structure 10, and therefore do not cause the area of each regular layer L1 or L2 to be increased. Further, in some embodiments, because the redundant layer RL replaces the defective regular layer L2, column redundancy multiplexing circuits used in the other approaches are not used. Therefore, the time for reading or writing data is decreased. In addition, in some embodiments, the layer L2 being replaced by the redundant layer RL is shut down, or if the redundant layer RL is not used, the redundant layer RL is shut down so that power is saved.

### Another Stacked Memory Structure With Redundancy

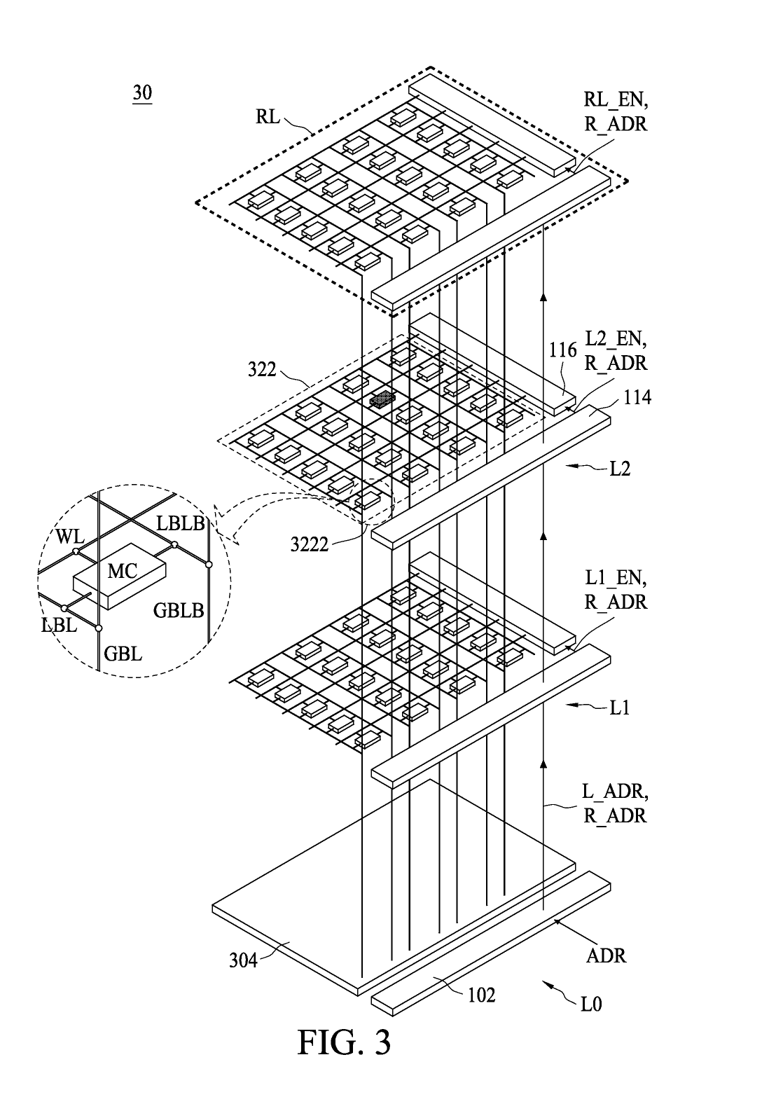

FIG. 3 is a schematic perspective diagram of a stacked memory structure 30 with layer redundancy in accordance with some embodiments. The stacked memory structure 30 in FIG. 3 is similar to the stacked memory structure 10 in FIG. 1 and is different in that the stacked memory structure 30 has local bit lines LBL and complementary local bit lines LBLB running in each layer L1, L2 or RL, and global bit lines GBL and global complementary bit lines GLBL running across layers L1, L2 and RL. The stacked memory structure 30 includes a control and IO layer L0, regular layers L1 and L2 and a redundant layer RL. The layer L0 includes a control circuit 102 and an IO circuit 304. Each of the layers L1, L2 and RL includes a memory array 322, a layer decoding circuit 114 and a row decoding circuit 116. The memory array 322 includes 4×4 memory cells MC, one of which configured with a global bit line GBL and a global complementary bit line GBLB is shown in a zoomed-in portion 3222 of the memory array 322. Memory cells MC in the same row has the same configuration as the memory cell MC in the zoomed-in portion 3222, and other memory cells of the memory array 322 are configured without the global bit line GBL and the global complementary bit line GBLB.

As illustrated in the zoomed-in portion 3222 of the memory array 322, the memory cell MC is coupled to a word line WL, a local bit line BL, a complementary local bit line LBLB, a global bit line GBL and a global complementary bit line GBLB. The word line WL is configured for passing of data to be written to and read from the memory cell MC to be controlled therethrough. The coupled local bit line LBL and global bit line GBL, and the coupled complementary local bit line LBLB and the complementary global bit line GBLB are configured for differential voltages representing the data to be written to or read from the memory cell MC to be passed therethrough.

In the stacked memory structure 30, each row of memory cells MC in each memory array 322 is coupled to a respective word line WL. Each horizontal column of memory cells MC in the same layer L1, L2 or RL is coupled to a respective local bit line LBL and a respective complementary local bit line LBLB. Each local bit line LBL and each complementary local bit line LBLB running horizontally along the corresponding layer L1, L2 or RL are coupled to a global bit line GBL and a complementary global bit line GBLB running vertically across different layers L1, L2 and RL, respectively. In some embodiments, the global bit line GBL and the complementary global bit line GBLB running vertically across different layers L1, L2 and RL are implemented using TSVs, ILVs, vias and/or metal lines.

The control circuit 102, the layer decoding circuit 114 and the row decoding circuit 116 are the same as those described with reference to FIG. 1 and are omitted here.

The IO circuit 304 is configured to send or receive data to or from the selected row in the layer L1, L2 or RL through the global bit lines GBL and the complementary global bit lines GBLB. The data to be written to the selected row is sent from the IO circuit 304 to the global bit lines GBL and the complementary global bit lines GBLB, and the local bit lines LBL and the complementary local bit lines LBLB and then the selected row. The data read from the selected row is sent from the selected row, the local bit lines LBL and the complementary local bit lines LBLB, the global bit lines GBL and the complementary global bit lines GLBL to the IO circuit 304.

In other embodiments (not illustrated), different layers L1, L2 and RL share a row decoding circuit 116 and therefore each of the layers L1, L2 and RL has a selected row. Each layer decoding circuit 114 in the corresponding layer L1, L2, or RL enables passing data between the selected row in the corresponding layer L1, L2 or RL and the IO circuit 304 based on the layer address L_ADR.

In some embodiments, a method for accessing the stacked memory structure 30 in FIG. 3 is similar to that described with reference to FIG. 2 and is different in operation 226. For the stacked memory structure 30, the IO circuit 304 sends or receives data to or from the row in the redundant layer RL through the global bit line GBL and the complementary global bit line GBLB. The operations similar to those of the method described with reference to FIG. 2 are omitted here.

The advantages of the embodiments described with reference to FIG. 3 are similar to those described with reference to FIG. 1 and are omitted here.

### Another Stacked Memory Structure With Redundancy

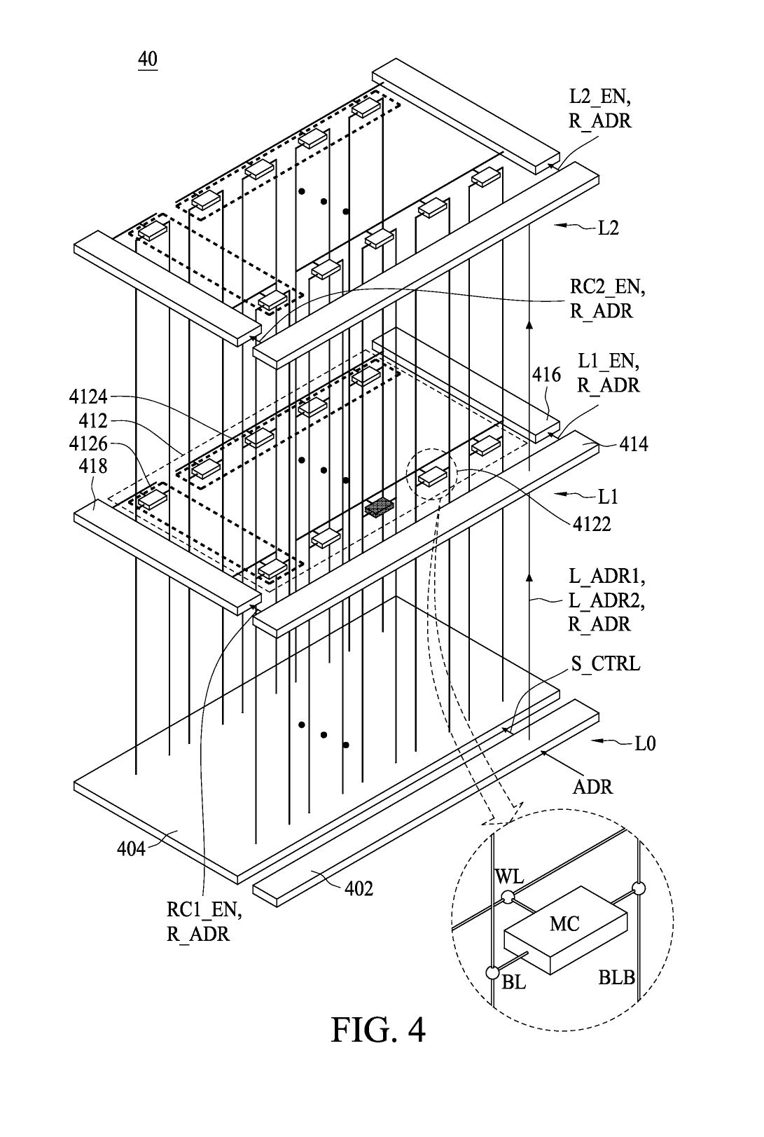

FIG. 4 is a schematic perspective diagram of a stacked memory structure 40 with row redundancy and/or column redundancy in accordance with some embodiments. In the illustration of FIG. 4, each layer L1 or L2 in the stacked memory structure 40 is configured with a redundant row 4124 for defective row in the same layer or a different layer, or defective rows among different layers to be replaced. A defective row is for example caused by one or more defective memory cells in the row, a defective word line of the row. Defective rows among different layers are for example caused by defective bit lines or complementary bit lines across different layers. Each layer L1 or L2 in the stacked memory structure 40 is also configured with a redundant column 4126 for a defective column in the same layer or a different layer, or defective columns among different layers to be replaced. A defective column is for example caused by one or more defective memory cells in a column in the same layer or a different layer. Defective columns among different layers are for example caused by defective bit lines or defective complementary bit lines across different layers. The stacked memory structure 40 includes a control and IO layer L0, a layer L1 and a layer L2. The layer L0 includes a control circuit 402 and an IO circuit 404. Each of the layers L1 and L2 includes a memory array 412, a layer decoding circuit 414, a row decoding circuit 416 for regular rows and the redundant row 4124, and a row decoding circuit 418 for the redundant column 4126. The memory array 412 includes 5×5 memory cells MC, wherein four of the rows are regular rows, and one of the rows is the redundant row 4124; and four of the columns are regular columns, and one of the columns is the redundant column 4126. One of the memory cell MC is shown in a zoomed-in portion 4122 of the memory array 412. Other memory cells MC of the memory array 112 have the same configuration as that shown in the zoomed-in portion 1122. The stacked memory structure 40 is exemplary. A stacked memory structure with other number of layers, other number of redundant rows and/or redundant columns, and other number of memory cells in each layer are within the contemplated scope of the present disclosure.

The zoomed-in portion 4122 of the memory array 412 is the same as the zoomed-portion 1122 of the memory array 112 and details of which are omitted here.

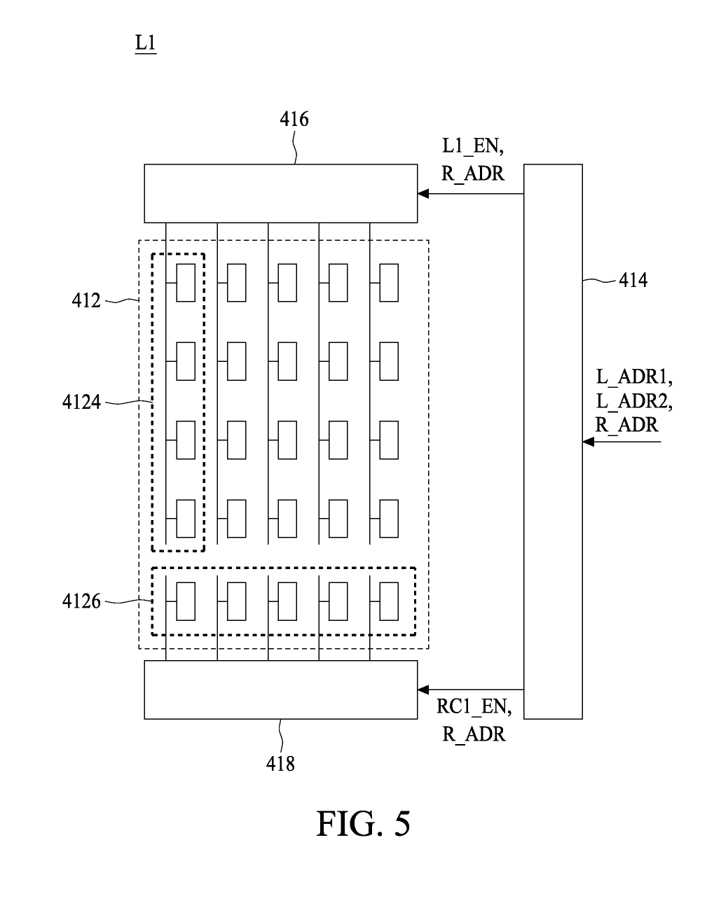

In the stacked memory structure 40, each regular row of memory cells MC in the corresponding layer L1 or L2 is coupled to a respective word line WL. The memory cells MC in each redundant row 4124 in the corresponding layer L1 or L2 is coupled to a word line WL. Each memory cell in the redundant column 4126 is coupled to a respective word line WL. FIG. 5 is a top-view diagram of the layer L1 in the stacked memory structure 40 in FIG. 4 in accordance with some embodiments. The top-view diagram for the layer L2 is the same as that for the layer L1. In FIG. 5, bit lines BL and complementary bit lines BLB of the layer L1 are not shown so that the word lines WL for the regular rows and the redundant row 4124, as well as the word lines WL for the redundant column 4126 obscured by the bit lines BL and complementary bit lines BLB in FIG. 4 are shown clearly. In FIG. 4, each vertical column of memory cells MC across different layers L1 and L2 is coupled to a bit line BL and a complementary bit line BLB. In some embodiments, the bit line BL and the complementary bit line BLB of each vertical column are implemented using TSVs, ILVs, vias and/or metal lines.

The control circuit 402 is configured to receive an address ADR of one or more memory cells to be accessed, generate a layer address L_ADR1 and a row address R_ADR for row redundancy, and/or generate a layer address L_ADR1, a layer address L_ADR2, a row address R_ADR and a shift control signal S_CTRL for column redundancy. For row redundancy, the control circuit 402 replaces a layer address in the address ADR with the layer address L_ADR1 of the layer L1 or L2 in which the redundant row 4124 replacing a defective regular row with the address ADR resides, and replaces a row address in the address ADR with the row address R_ADR of the redundant row 4124. In some embodiments, the control circuit 402 includes fuses programmed for converting a matched address ADR of the defective regular row into the layer address L_ADR1 and the row address R_ADR of the redundant row 4124 in the same or different layer. For column redundancy , the control circuit 402 generates the layer address L_ADR1 and the row address R_ADR using the layer address and the row address in the address ADR. Further, the control circuit 402 generates the layer address L_ADR2 of the layer L1 or L2 in which the redundant column 4126 for a memory cell in the regular row with the address ADR or the redundant row 4124 based on the address ADR to be replaced resides. In addition, the control circuit 402 generates the shift control signal S_CTRL when the layer address L_ADR2 of the layer L1 or L2 in which the redundant column 4126 is generated. In some embodiments, the control circuit 402 includes fuses programmed for generating, based on a matched address ADR of a defective column, the layer address L_ADR2 and the row address R_ADR of the memory cell in the redundant column 4126 in the same or different layer and for generating the shift control signal S_CTRL correspondingly.

Each layer decoding circuit 414 is configured to receive the layer addresses L_ADR1 and L_ADR2, and the row address R_ADR from the control circuit 402, and generate an asserted layer enable signal L1_EN or L2_EN if the received layer address L_ADR1 corresponds to the residing layer L1 or L2 of the layer decoding circuit 414. The layer decoding circuit 414 is also configured to generate an asserted redundant column enable signal RC1_EN or RC2_EN if the received layer address L_ADR2 corresponds to the residing layer L1 or L2 of the layer decoding circuit 414. Each layer decoding circuit 414 is also configured to pass the row address R_ADR along with the layer enable signal L1_EN or L2_EN and the redundant column enable signal RC1_EN or RC2_EN. In some embodiments, the layer addresses L_ADR1 and L_ADR2 and the row address R_ADR are passed vertically along different layers L1 and L2 using TSVs, ILVs, vias and/or metal lines. In other embodiments, the layer addresses L_ADR1 and L_ADR2 and the row address R_ADR are passed along different layers L1 and L2 using TSVs, ILVs, vias and/or metal lines.

Each row decoding circuit 416 is configured to receive the layer enable signal L1_EN or L2_EN and the row address R_ADR from the corresponding layer decoding circuit 414, and selects one of the rows in the corresponding memory array 412 based on the row address R_ADR when the layer enable signal L1_EN or L2_EN is asserted.

Each row decoding circuit 418 is configured to receive the redundant column enable signal RC1_EN or RC2_EN and the row address R_ADR from the corresponding layer decoding circuit 414, and selects one of the memory cell in the corresponding redundant column 4126 based on the row address R_ADR when the redundant column enable signal RC1_EN or RC2_EN is asserted.

The IO circuit 404 is configured to send or receive data to or from the selected row in the layer L1 or L2 through the corresponding bit lines BL and complementary bit lines BLB. The IO circuit 404 includes for each vertical column of memory cells, a sense amplifier, data driver and flip flop or latch circuit, not shown for simplicity. The sense amplifier, data driver and flip flop or latch circuit are the same as those described with reference to FIG. 1 and are omitted here. In addition, the IO circuit 404 includes column redundancy multiplexing circuits, not shown for simplicity, configured to shift, in response to the shift control signal S_CTRL, data of the redundant column 4126 and intermediate columns before the column with one or more memory cells to be replaced.

The organization of functional blocks in FIG. 4 is exemplary. For example, in other embodiments, the layer decoding circuits 414 of the layers L1 and L2 are configured in the control circuit 402, and the control circuit 402 generates the layer enable signals L1_EN and L2_EN, the redundant column enable signals RC1_EN and RC2_EN, as well as the row address R_ADR based on the received address ADR. The enable signals L1_EN, L2_EN, RC1_EN, and RC2_EN and the row address R_ADR are passed vertically to the corresponding layer L1 or L2.

### Method for Accessing Stacked Memory Structure With Redundancy

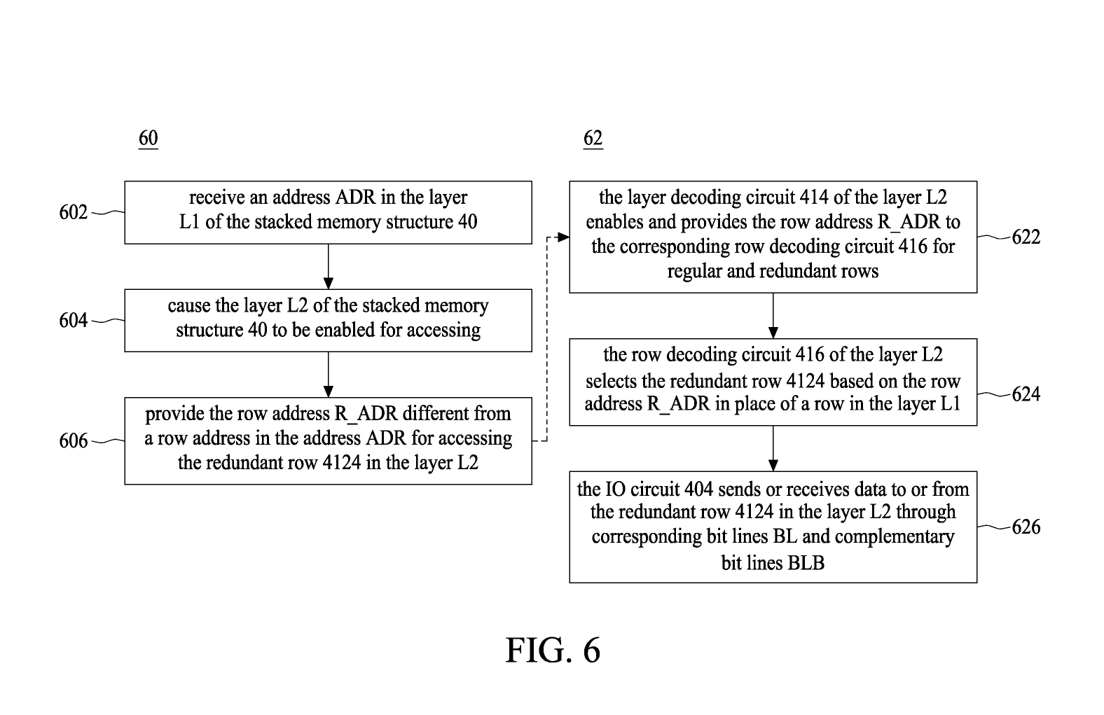

FIG. 6 is a diagram showing flow charts 60 and 62 of a method for accessing the stacked memory structure 40 in FIG. 4 in accordance with some embodiments. In the illustration of FIG. 6, a row repaired by a redundant row 4124 in a different layer is accessed. Similar operations apply to a row repaired by a redundant row 4124 in the same layer. The flow chart 60 includes operations performed by the control circuit 402, and the flow chart 62 includes operations performed by other portions of the stacked memory structure 40 in response to the operations of the control circuit 402.

In the flow chart 60, in operation 602, an address ADR in the layer L1 of the stacked memory structure 40 is received.

In operation 604, the layer L2 of the stacked memory structure 40 is caused to be enabled for accessing. In some embodiments, the control circuit 402 converts a layer address and a row address received in the address ADR to the layer address L_ADR1 and the row address R_ADR of the redundant row 4124 in the layer L2, and sends the layer address L_ADR1 to cause the layer L2 to be enabled. In other embodiments, the layer L1 the same as the layer of the row with the address ADR is enabled instead.

In operation 606, the row address R_ADR different from the row address in the address ADR is provided for accessing the redundant row 4124 in the layer L2. In other embodiments, when the layer L1 is enabled, a row address in the address ADR is used as the row address R_ADR for accessing the redundant row 4124 in the layer L1.

In the flow chart 62, in operation 622, in response to the received layer address L_ADR and row address R_ADR, the row decoding circuit 416 for the regular and redundant rows is enabled and provided with the row address R_ADR by the layer decoding circuit 414. In some embodiments, the layer decoding circuit 414 of the layer L2 sends an asserted layer enable signal L2_EN to enable the corresponding row decoding circuit 416.

In operation 624, the redundant row 4124 in the layer L2 is selected based on the row address R_ADR by the row decoding circuit 416 of the layer L2 to replace a row in the layer L1.

In operation 626, data are sent to or received from the redundant row 4124 in the layer L2 by the IO circuit 404 through corresponding bit lines BL and complementary bit lines BLB.

### Another Method for Accessing Stacked Memory Structure With Redundancy

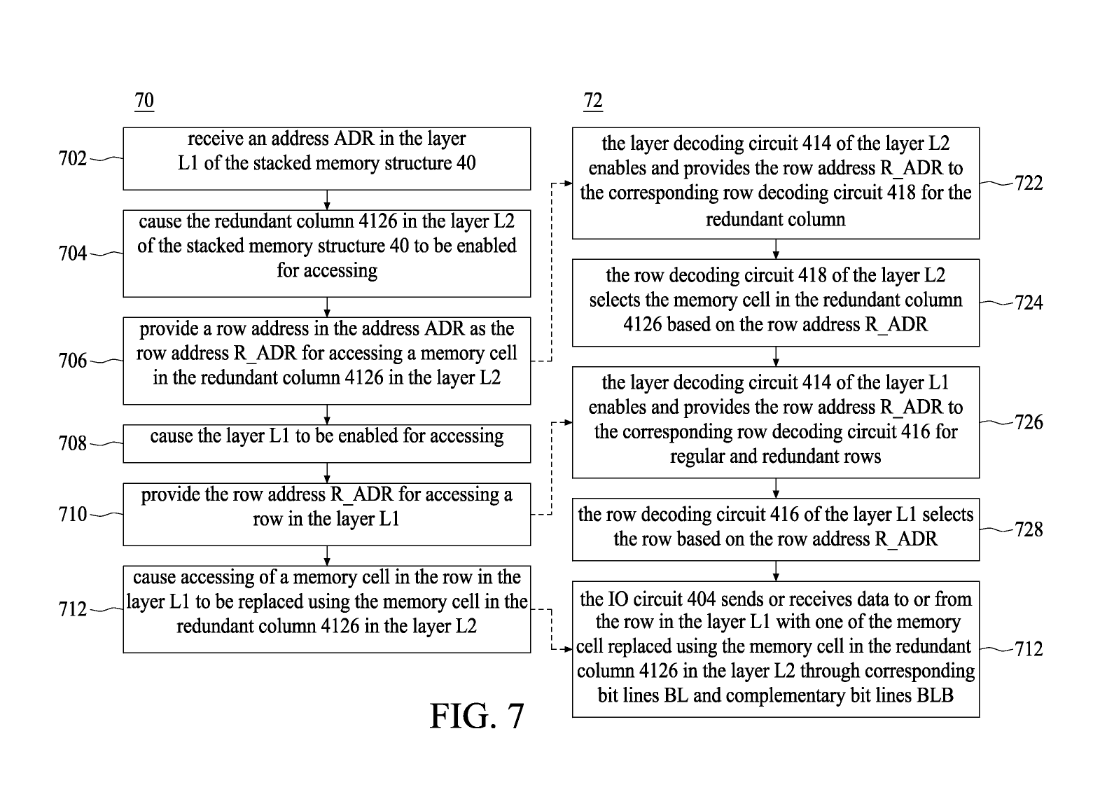

FIG. 7 is a diagram showing flow charts 70 and 72 of a method for accessing the stacked memory structure 40 in FIG. 4 in accordance with some embodiments. In the illustration of FIG. 7, a row with a memory cell repaired by a memory cell in a redundant column 4126 in a different layer is accessed. Similar operations apply to a row with a memory cell repaired by a redundant column 4126 in the same layer. The flow chart 70 includes operations performed by the control circuit 402, and the flow chart 72 includes operations performed by other portions of the stacked memory structure 40 in response to the operations of the control circuit 402.

In the flow chart 70, in operation 702, an address ADR in the layer L1 of the stacked memory structure 40 is received.

In operation 704, the redundant column 4126 in the layer L2 of the stacked memory structure 40 is caused to be enabled for accessing. In some embodiments, the control circuit 502 generates, based on a layer address and a row address received in the address ADR, the layer address L_ADR2 of the redundant column 4126 in the layer L2, and sends the layer address L_ADR2 to cause the redundant column 4126 of the layer L2 to be enabled. In other embodiments, the redundant column 4126 of the layer L1 the same as the layer of the row with the address ADR is enabled instead.

In operation 706, a row address in the address ADR is used as the row address R_ADR for accessing a memory cell in the redundant column 4126 in the layer L2. In other embodiments, when the layer L1 is enabled, a row address in the address ADR is used as the row address R_ADR for accessing a memory cell in the redundant column 4126 in the layer L1.

In the flow chart 72, in operation 722, in response to the received layer address L_ADR2 and row address R_ADR, the row decoding circuit 418 for the redundant column is enabled and provided with the row address R_ADR by the layer decoding circuit 414. In some embodiments, the layer decoding circuit 414 of the layer L2 sends an asserted redundant column enable signal RC2_EN to enable the corresponding row decoding circuit 418.

In operation 724, the memory cell in the redundant column 4126 of the layer L2 is selected based on the row address R_ADR by the row decoding circuit 418 of the layer L2.

In the flow chart 70, in operation 708, the layer L1 is caused to be enabled for accessing. In some embodiments, the control circuit 402 sends the layer address in the address ADR to cause the layer L1 to be enabled.

In operation 710, the row address R_ADR is provided for accessing a row in the layer L1.

In the flow chart 72, in operation 726, in response to the received layer address L_ADR1 and row address R_ADR, the row decoding circuit 416 for the regular and redundant rows is enabled and provided with the row address R_ADR by the layer decoding circuit 414 of the layer L1. In some embodiments, the layer decoding circuit 414 of the layer L1 sends an asserted layer enable signal L1_EN to enable the corresponding row decoding circuit 416.

In operation 728, the row in the layer L1 is selected based on the row address R_ADR by the row decoding circuit 416.

In the flow chart 70, in operation 712, accessing of a memory cell in the row in the layer L1 is caused to be replaced using the memory cell in the redundant column 4126 in the layer L2. In some embodiments, the control circuit 402 sends the shift control signal S_CTRL to the column redundancy multiplexing circuits in the IO circuit 404 to cause replacement of the memory cell in the row in the layer L1.

In the flow chart 72, in operation 712, data are sent to or received from the row in the layer L1 with one of the memory cell replaced using the memory cell in the redundant column 4126 in the layer L2 by the IO circuit 404 through corresponding bit lines BL and complementary bit lines BLB.

In the embodiments described with reference to FIG. 4, the redundant row 4124 and the redundant column 4126 of each layer L1 or L2 can be used to repair a row or a column in the same layer or a different layer in the stacked memory structure 40. Therefore, for two defective rows or columns in a layer, L2 for example, the redundant row or column in another layer, L1 for example, can be used in addition to the redundant row or column in the same layer L2. As a result, the memory array 412 of the layer L2 do not need to be expanded along the x dimension to include an additional redundant row, and do not need to be expanded along the y dimension to include an additional redundant column. Compared to other approaches, the area of each layer of the stacked memory structure 40 is smaller. Further, because the number of redundant columns in each layer is reduced, the number of shift operations performed by the column redundancy multiplexing circuits in the other approaches is reduced. Therefore, the time for reading or writing data is decreased.

### Another Stacked Memory Structure With Redundancy

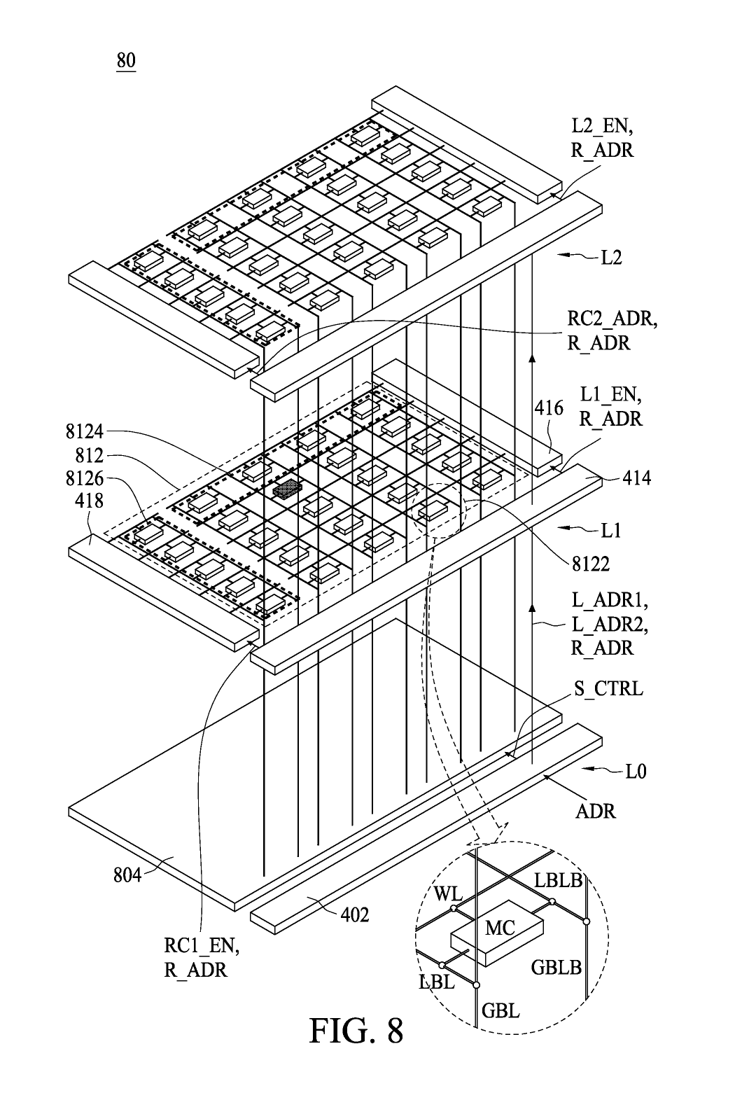

FIG. 8 is a schematic perspective diagram of a stacked memory structure 80 with row redundancy and/or column redundancy in accordance with some embodiments. The stacked memory structure 80 is similar to the stacked memory structure 40 in FIG. 4 and is different in that the stacked memory structure 80 has local bit lines LBL and complementary local bit lines LBLB running in each layer L1 or L2, and global bit lines GBL and global complementary bit lines GLBL running across layers L1 and L2. The stacked memory structure 80 includes a control and IO layer L0, a layer L1 and a layer L2. The layer L0 includes a control circuit 402 and an IO circuit 804. Each of the layers L1 and L2 includes a memory array 812, a layer decoding circuit 414 and a row decoding circuit 416 for regular and redundant rows and a row decoding circuit 418 for a redundant column. The memory array 812 includes 5×5 memory cells MC, one of which configured with a global bit line GBL and a global complementary bit GBLB is shown in a zoomed-in portion 8122 of the memory array 812. Memory cells MC in the same row has the same configuration as the memory cell MC in the zoomed-in portion 8122, and other memory cells of the memory array 812 are configured without the global bit line GBL and the global complementary bit line GBLB.

The zoomed-in portion 8122 is the same as that shown in the zoomed-in portion 3222 in FIG. 3 and details of which are omitted here.

In the stacked memory structure 80, the word line configurations for each regular row, redundant row 8124 and memory cells in each redundant column 8126 are similar to those of the stacked memory structure 40 in FIG. 4. Each horizontal column of memory cells MC in the same layer L1 or L2 is coupled to a respective local bit line LBL and a respective complementary local bit LBLB. Each local bit line LBL and each complementary local bit line LBLB running horizontally along the corresponding layer L1 or L2 are coupled to a global bit line GLB and a complementary global bit line GLBL running vertically across different layers L1 and L2, respectively. In some embodiments, the global bit line GBL and the complementary global bit line GBLB running vertically across different layers L1 and L2 are implemented using TSVs, ILVs, vias and/or metal lines.

The control circuit 402, the layer decoding circuit 414 and the row decoding circuit 416 are the same as those described with reference to FIG. 1 and are omitted here.

The IO circuit 804 is configured to send or receive data to or from the selected row in the layer L1 or L2 through the global bit lines GBL and the complementary global bit lines GBLB. The signal flows for writing or read data between the layer L1 or L2 and the IO circuit 804 are similar to those described with reference to FIG. 3 and are omitted here. In the IO circuit 804, similar to the IO circuit 404 in FIG. 4, column redundancy multiplexing circuits are configured to shift, in response to the shift control signal S_CTRL, data of the redundant column 8126 and intermediate columns between the redundant column 8126 and the defective column.

In other embodiments (not illustrated), different layers L1 and L2 share a row decoding circuit 416 and share a row decoding circuit 418, and therefore, each of the layers has a selected regular or redundant row, and a selected memory cell in the corresponding redundant column. Each layer decoding circuit 414 in the corresponding layer L1 or L2 enables passing data between the selected regular or redundant row and the IO circuit 804 based on the layer address L_ADR1, and enables passing data between the selected memory cell in corresponding redundant column 8126 and the IO circuit 804 based on the layer address L_ADR2.

In some embodiments, methods for accessing the stacked memory structure 80 in FIG. 8 are similar to those described with reference to FIGS. 6 and 7 and is different in operation 626 in FIG. 6, and in operation 712 in FIG. 7. For the stacked memory structure 80, in operation 626 and in operation 712, the IO circuit 804 sends or receives data through the global bit line GBL and the complementary global bit line GBLB. The operations similar to those of the methods described with reference to FIGS. 6 and 7 are omitted here.

The advantages of the embodiments described with reference to FIG. 8 are similar to those described with reference to FIG. 4 and are omitted here.

In some embodiments, a stacked memory structure is configured with a redundant layer for replacing a defective layer. In some embodiments, a stacked memory structure is configured with a redundant row and/or a redundant column in each layer and the redundant row or column in one layer is used to repair a defective row or column. As a result, compared with area of the memory chip in the other approach, the area of one layer in the stacked memory structure is smaller. Further, compared with the other approach, the time for reading or writing data is reduced due to less shift operations for column redundancy.

In some embodiments, in a method, a first address in a first layer of stacked memory arrays is received. A second layer of stacked memory arrays is caused to be enabled for accessing. A second row address for accessing the second layer is provided.

In some embodiments, a circuit comprises stacked memory arrays and a control circuit. The stacked memory arrays comprises a first layer and a second layer. The control circuit is configured to receive a first address in the first layer; cause the second layer to be enabled for accessing; and provide a second row address for accessing the second layer.

In some embodiments, a circuit comprises a stacked memory structure and a control circuit. The stacked memory structure comprises a first layer and a second layer. Each of the first and second layers comprises a memory array and a first row decoding circuit. The first row decoding circuit is configured to access a row in the memory array. The control circuit is configured to receive a first address in the memory array of the first layer; cause the first row decoding circuit of the second layer to be enabled; and provide a second row address to the row decoding circuit of the second layer.

The above description includes exemplary operations, but these operations are not necessarily required to be performed in the order shown. Operations may be added, replaced, changed order, and/or eliminated as appropriate, in accordance with the spirit and scope of the disclosure. Accordingly, the scope of the disclosure should be determined with reference to the following claims, along with the full scope of equivalences to which such claims are entitled.

What is claimed is:

1. A method, comprising:
receiving a first address in a first layer of stacked memory arrays;
causing a second layer of stacked memory arrays to be enabled for accessing; and
providing a second row address for accessing the second layer.

2. The method according to claim 1, wherein providing a second row address for accessing the second layer comprises:
providing a first row address in the first address as the second row address for selecting a row in the second layer.

3. The method according to claim 1, wherein providing a second row address for accessing the second layer comprises:
providing a first row address in the first address as the second row address for selecting a memory cell in a first column in the second layer.

4. The method according to claim 3, further comprising:
causing the first layer to be enabled for accessing; and
providing the first row address of the first layer for selecting a row in the first layer.

5. The method according to claim 3, further comprising:
causing data of the memory cell in the first column in the second layer to be shifted for data of a memory cell in the first layer to be replaced.

6. The method according to claim 3, further comprising:
receiving a third address of the first layer;
causing the first layer to be enabled for accessing; and
providing a third row address in the third address for selecting a memory cell in a first column in the first layer.

7. The method according to claim 1, wherein providing a second row address for accessing the second layer comprises:
providing the second row address different from a first row address in the first address for selecting a redundant row in the second layer.

8. The method according to claim 7, further comprising:
receiving a third address of the first layer;
causing the first layer to be enabled for accessing; and
providing a fourth row address different from a third row address in the third address for selecting a redundant row in the first layer.

9. A circuit, comprising:
stacked memory arrays comprising a first layer and a second layer; and
a control circuit, configured to
receive a first address in the first layer;
cause the second layer to be enabled for accessing; and
provide a second row address for accessing the second layer.

10. The circuit according to claim 9, further comprising:
a row decoding circuit, configured to select a row in the second layer based on the second row address,
wherein
the control circuit provides a first row address in the first address as the second row address to the row decoding circuit.

11. The circuit according to claim 9, further comprising:
at least one first row decoding circuit, configured to select a memory cell in a first column in the second layer based on the second row address,
wherein
the control circuit provides a first row address in the first address as the second row address to the at least one first row decoding circuit.

12. The circuit according to claim 11, wherein
the circuit further comprises at least one second row decoding circuit;
the control circuit is further configured to cause the first layer to be enabled for accessing; and
the at least one second row decoding circuit is configured to select a row in the first layer based on the first row address.

13. The circuit according to claim 11, further comprising:
a redundancy multiplexing circuit, configured to shift data of the memory cell in the first column in the second layer to replace data of a memory cell in the first layer.

14. The circuit according to claim 11, wherein
the at least one first row decoding circuit is further configured to select a memory cell in a first column in the first layer based on a third row address; and
the control circuit is further configured to:
receive a third address of the first layer;
cause the first layer to be enabled for accessing; and
provide the third row address in the third address to the at least one first row decoding circuit.

15. The circuit according to claim 9, further comprising:
at least one row decoding circuit, configured to select a row in the second layer based on the second row address,
wherein
the control circuit provides the second row address different from the first row address to the at least one row decoding circuit.

16. The circuit according to claim 15, wherein
the at least one row decoding circuit is further configured to select a row in the first layer based on a fourth row address; and
the control circuit is further configured to:
receive a third address of the first layer;
cause the first layer to be enabled for accessing; and
provide the fourth row address different from a third row address in the third address to the at least one row decoding circuit.

17. A circuit, comprising:
a stacked memory structure comprising a first layer and a second layer,
wherein
each of the first and second layers comprises:
a memory array; and
a first row decoding circuit, configured to access a row in the memory array; and
a control circuit, configured to
receive a first address in the memory array of the first layer;
cause the first row decoding circuit of the second layer to be enabled; and
provide a second row address to the row decoding circuit of the second layer.

18. The circuit according to claim 17, wherein each of the first and second layers further comprises:
a layer decoding circuit, configured to enable the respective first row decoding circuit in response to a corresponding layer address,
wherein
the control circuit is configured to provide a second layer address to the layer decoding circuit of the second layer in response to a received first layer address in the first address to cause the first row decoding circuit of the second layer to be enabled.

19. The circuit according to claim 17, wherein
the control circuit provides a first row address in the first address as the second row address to the first row decoding circuit of the second layer.

20. The circuit according to claim 17, wherein
each of the first and second layers further comprises:
a second row decoding circuit, configured to access a memory cell in a first column of the respective layer; and
the control circuit provides a first row address in the first address as the second row address to the second row decoding circuit of the second layer.

21. The circuit according to claim 20, wherein the control circuit is further configured to:
cause the first row decoding circuit of the first layer to be enabled; and
provide the first row address in the first address to the first row decoding circuit of the first layer.

22. The circuit according to claim 20, further comprising:
a redundancy multiplexing circuit, configured to shift data of the memory cell in the first column in the second layer to replace data of a memory cell in the first layer.

23. The circuit according to claim 20, wherein the control circuit is further configured to:
receive a third address of the first layer;
cause the second row decoding circuit of the first layer to be enabled; and
provide the third row address in the third address to the second row decoding circuit of the first layer.

24. The circuit according to claim 17, wherein
the control circuit provides the second row address different from the first row address to the first row decoding circuit of the first layer.

25. The circuit according to claim 24, wherein the control circuit is further configured to:
receive a third address of the first layer;
cause the first row decoding circuit of the first layer to be enabled; and
provide a fourth row address different from a third row address in the third address to the first row decoding circuit in the first layer.
